(19) United States
(12) Patent Application Publication
(10) Pub. No.: US 2025/0056834 A1
(43) Pub. Date: Feb. 13, 2025

(54) P-TYPE LATERALLY DIFFUSED METAL OXIDE SEMICONDUCTOR DEVICE AND MANUFACTURING METHOD THEREFOR

(71) Applicants: SOUTHEAST UNIVERSITY, Jiangsu (CN); CSMC TECHNOLOGIES FAB2 CO LTD., Jiangsu (CN)

(72) Inventors: Long ZHANG, Jiangsu (CN); Nailong HE, Jiangsu (CN); Yongjiu CUI, Jiangsu (CN); Sen ZHANG, Jiangsu (CN); Xiaona WANG, Jiangsu (CN); Feng LIN, Jiangsu (CN); Jie MA, Jiangsu (CN); Siyang LIU, Jiangsu (CN); Weifeng SUN, Jiangsu (CN)

(21) Appl. No.: 18/722,930

(22) PCT Filed: Nov. 30, 2022
(86) PCT No.: PCT/CN2022/135331

§ 371 Date: Jun. 21, 2024

(30) Foreign Application Priority Data
Feb. 25, 2022 (CN) 202210181654.3

(51) Int. Cl. H01L 29/78; H01L 21/266; H01L 29/06; H01L 29/40; H01L 29/66

(52) U.S. Cl. CPC H01L 29/7823; H01L 21/266; H01L 29/0607; H01L 29/402; H01L 29/66681; H01L 29/7824

(57) ABSTRACT

A manufacturing method for a P-type laterally diffused metal oxide semiconductor device includes: forming a N-type buried layer in a substrate, forming a P-type region located on the N-type buried layer, and forming a mask layer located on the P-type region; patterning the mask layer to form at least two injection windows; performing N-type ion implantation by the at least two injection windows; forming an oxide layer; removing the mask layer; performing P-type ion implantation on the P-type region to form a P-type doped region; diffusing the P-type doped region to form a drift region and two P-type well regions, diffusing the high-voltage N-well doped region to form a high-voltage N-type well region, and diffusing the low-voltage N-well doped region to form a low-voltage N-type well region; and forming a source doped region, a drain doped region, and a gate.

### CROSS-REFERENCE TO RELATED APPLICATIONS

This application claims priority to Chinese Patent Application No. 2022101816543, entitled “P-TYPE LATERALLY DIFFUSED METAL OXIDE SEMICONDUCTOR DEVICE AND MANUFACTURING METHOD THEREFOR”, filed on Feb. 25, 2022, the content of which is incorporated herein by reference in its entirety.

### TECHNICAL FIELD

The present disclosure relates to the technical field of semiconductor integrated circuit, and particularly relates to a P-type laterally diffused metal oxide semiconductor device, and a method for manufacturing the P-type laterally diffused metal oxide semiconductor device.

### BACKGROUND

High-voltage integrated circuit is an important field of power electronics. It integrates a high-voltage power component with a signal processing system, a peripheral interface circuit, a protection circuit, and a detection circuit into a chip, which not only improves the reliability and stability of the system, but also reduces the power consumption, volume, weight, and cost of the system. In a high-voltage integrated circuit, when a potential of a high-side circuit is high, a level shift technology is required to transmit a low-voltage signal to a high-voltage part, so as to drive a high-voltage end power device. A level shift circuit is a bridge connecting high- and low-voltage circuits, which raises a low-voltage signal output by the pre-stage dead-zone generating circuit to a high-voltage signal for a post-stage high-voltage circuit, preventing cross-talk of the high- and low-voltage signals between a pre-stage and a post-stage. A high-voltage power conversion device LDMOS is key to the level shift circuit, a gate end thereof receives a signal of a low-side circuit and outputs a high-voltage signal through a drain end thereof, such that LDMOS needs to withstand a voltage of the high-side circuit. Breakdown voltage is an important parameter to measure LDMOS devices. Breakdown voltage is the maximum voltage that can be withstood at the drain end when high voltage is applied to the drain end of LDMOS, and the gate and source are at the zero potential. When the voltage at the drain end exceeds the breakdown voltage of the device, avalanche breakdown occurs. When the device is in avalanche breakdown for a long time, the device burns. LDMOS is widely used in high-voltage power integrated circuits due to good switching characteristics and high breakdown voltage.

PLDMOS is a type of LDMOS having excellent performance of LDMOS, which can also serve as a high-side driver to simplify complexity of a power integrated circuit and reduce a chip area. However, unlike manufacturing process of conventional NLDMOS, an exemplary manufacturing process of PLDMOS is more complex.

### SUMMARY

According to some embodiments, a method for manufacturing a P-type laterally diffused metal oxide semiconductor device is provided.

The method for manufacturing a P-type laterally diffused metal oxide semiconductor device includes: forming an N-type buried layer in a substrate, forming a P-type region on the N-type buried layer, and forming a mask layer on the P-type region: patterning the mask layer to form at least two implantation windows: performing an N-type ion implantation through the at least two implantation windows to form a high-voltage N-well doped region and a low-voltage N-well doped region in the P-type region, wherein a doping concentration of the low-voltage N-well doped region is higher than a doping concentration of the high-voltage N-well doped region: forming an oxide layer on a surface of the P-type region at each implantation window; removing at least a part of the mask layer: performing a P-type ion implantation on the P-type region to form a P-type doped region: diffusing the P-type doped region by a thermal annealing to form a drift region and two P-type well regions, diffusing the high-voltage N-well doped region to form a high-voltage N-type well region, and diffusing the low-voltage N-well doped region to form a low-voltage N-type well region: wherein the drift region is located between the high-voltage N-type well region and the low-voltage N-type well region, the two P-type well regions are located on two sides of the high-voltage N-type well region, respectively, and one of the two P-type well region is located between the high-voltage N-type well region and the drift region; and forming a source doped region, a drain doped region, and a gate: wherein the source doped region is located in the low-voltage N-type well region, the drain doped region is located in one P-type well region and is located between the high-voltage N-type well region and the drift region, the gate is located between the source doped region and the drain doped region, and the source doped region and the drain doped region have P-type doping.

A P-type laterally diffused metal oxide semiconductor device is provided, comprising: a substrate; an N-type buried layer provided in the substrate; a P-type region provided on the N-type buried layer and the substrate; a high-voltage N-type well region, a low-voltage N-type well region, a drift region, and two P-type well regions that are provided in the P-type region: a field effect oxide layer provided on the P-type region: a gate located on the low-voltage N-type well region and the field effect oxide layer: a body region and a source doped region that are provided in the low-voltage N-type well region, wherein the body region is connected to a body region metal electrode, and the source doped region is located between the gate and the body region and is connected to a source metal electrode: a substrate leading-out region provided in one of the two P-type well regions, and connected to a substrate leading-out region metal electrode; and a drain doped region provided in another of the two P-type well region, wherein the drain doped region is located between the high-voltage N-type well region and the drift region and is connected to a drain metal electrode.

The details of one or more embodiments of the present disclosure are set forth in the accompanying drawings and the description below. Other features, objects and advantages of the present disclosure will become apparent from the description, the accompanying drawings, and the claims.

### BRIEF DESCRIPTION OF THE DRAWINGS

To better describe and illustrate the embodiments and/or examples of the disclosure disclosed herein, reference may be made to one or more accompanying drawings. The additional details or examples used to describe the accompanying drawings are not to be construed as limiting the scope of any one of the disclosed disclosures, the presently described embodiments and/or examples, and the presently understood preferred mode of the disclosure.

FIG. 1 is a flowchart of a method for manufacturing a P-type laterally diffused metal oxide semiconductor device according to an embodiment.

FIG. 2a is a cross-sectional view of a device structure after step S120 is completed according to an embodiment.

FIG. 2b is a cross-sectional view of a device structure after a first implantation in step S130 is completed according to an embodiment.

FIG. 2c is a cross-sectional view of a device structure after a second implantation in step S130 is completed according to an embodiment.

FIG. 2d is a cross-sectional view of a device structure after step S140 is completed according to an embodiment, and FIG. 2e is a cross-sectional view of a device structure after step S160 is completed according to an embodiment.

FIG. 2f is a schematic view of a drift region, a P-type well region, a high-voltage N-type well region, and a low-voltage N-type well region after a second thermal annealing according to an embodiment.

FIG. 3 is a cross-sectional view of a P-type laterally diffused metal oxide semiconductor device according to an embodiment.

### DETAILED DESCRIPTION OF EMBODIMENTS

For the convenience of understanding the present disclosure, the present disclosure is described more fully hereinafter with reference to the accompanying drawings. Preferable embodiments are presented in the accompanying drawings. However, the present disclosure may be embodied in many different forms and is not limited to the embodiments described herein. Rather, the purpose of providing these embodiments is to make the present disclosure more thorough and comprehensive.

All technical and scientific terms used herein have the same meaning as commonly understood by persons skilled in the art to which the present disclosure belongs, unless otherwise defined. The terms used in the specification of the present disclosure herein are for the purpose of describing specific embodiments only and are not intended to limit the present disclosure. The term “and/or” used herein includes any and all combinations of one or more of the associated listed items.

It should be understood that when an element or a layer is referred to as “above”, “adjacent to”, “connected to”, or “coupled to” other elements or layers, it may be directly located on, adjacent to, connected to, or coupled to other elements or layers, or there may be an intermediate element or layer. On the contrary, when an element is referred to as “directly above”, “directly adjacent to”, “directly connected to”, or “directly coupled to” other elements or layers, there is no intermediate element or layer. It should be understood that although the terms first, second, third and the like may be used to describe various elements, components, regions, layers and/or parts, these elements, components, regions, layers and/or parts shall not be limited by these terms. These terms are used only to differentiate one element, component, region, layer or part from another element, component, region, layer or part. Therefore, without departing from teachings of the present disclosure, the first element, component, region, layer or part discussed hereinafter may be referred as a second element, component, region, layer or part.

The spatial relationship terms, for example, “below”, “underneath”, “underlying”, “under”, “above”, “upper”, and the like may be used herein for descriptive convenience to describe a relationship between one element or feature and another element or feature shown in the drawings. It should be understood that in addition to the orientations shown in the figure, the spatial relationship terms are further intended to include different orientations of the device in use and operation. For example, if the device shown in the accompany drawings is reversed, then elements and features described as being “underneath” or “under” or “below” other elements will be oriented as being “above” other elements or features. Therefore, the exemplary term “underneath” and “below” may include both up and down orientations. The device may be otherwise oriented (rotated by 90 degrees or other orientations) and the spatial descriptors used herein are interpreted accordingly.

Terms used herein are for the purpose of describing specific embodiments only and are not intended to be limiting of the present disclosure. As used herein, “a”, “one” and “said/the” in singular forms are also intended to include a plural form unless the context clearly indicates other forms. It should also be understood that the terms “consist” and/or “include” when used in the description, determine presence of the features, integers, steps, operations, elements and/or components, but do not exclude the presence or addition of one or more other features, integers, steps, operations, elements, components, and/or groups. As used herein, the terms “and/or” include any and all combinations of related listed items.

The embodiments of the present disclosure are described herein with reference to a cross-sectional view that is a schematic view of an ideal embodiment (and an intermediate structure) of the present disclosure. In this way, a change from the shown shape due to, for example, manufacturing technology and/or tolerance may be expected. Therefore, embodiments of the present disclosure should not be limited to the specific shapes of the regions shown herein, but rather include shape deviations due to, for example, manufacturing. For example, an implantation region displayed as a rectangle generally has a circular or curved feature and/or implantation concentration gradient at its edge, rather than a binary change from the implantation region to a non-implantation region. Similarly, a buried region formed by implantation may result in some implantation into a region between the buried region and a surface over which implantation is performed. Therefore, the regions displayed in the drawings are substantially exemplary, and shapes thereof are not intended to display actual shapes of the regions of the device, and is not intended to limit the scope of the present disclosure.

The terms used herein are commonly used by persons skilled in the art. For example, for P-type and N-type impurities, in order to differentiate the doping concentration, simply referring P-type with a heavy doping concentration as P+ type, P-type with a medium doping concentration as P type, P-type with a light doping concentration as P-type, N-type with a heavy doping concentration as N+ type, N-type with a medium doping concentration as N type, N-type with a light doping concentration as N-type.

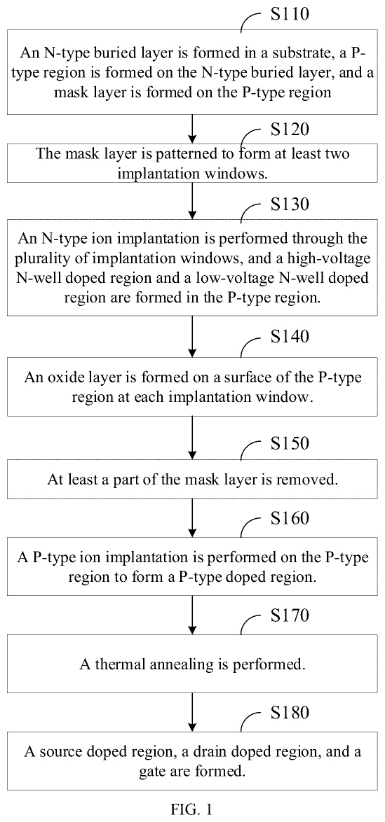

In order to simplify a manufacturing process of PLDMOS and make it compatible with a manufacturing process of NLDMOS, a method for manufacturing a P-type laterally diffused metal oxide semiconductor device is provided according to an embodiment. Referring to FIG. 1, the method includes the following steps:

Step 110, an N-type buried layer is formed in a substrate, a P-type region is formed on the N-type buried layer, and a mask layer is formed on the P-type region.

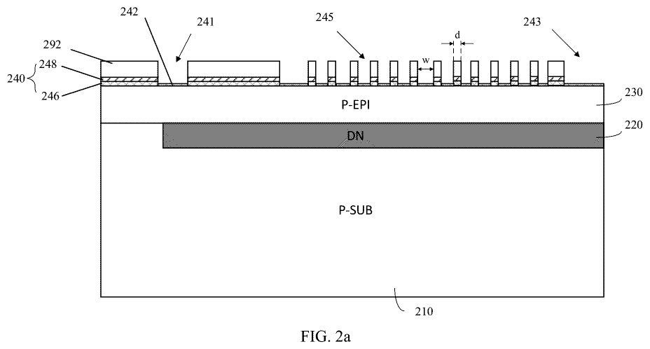

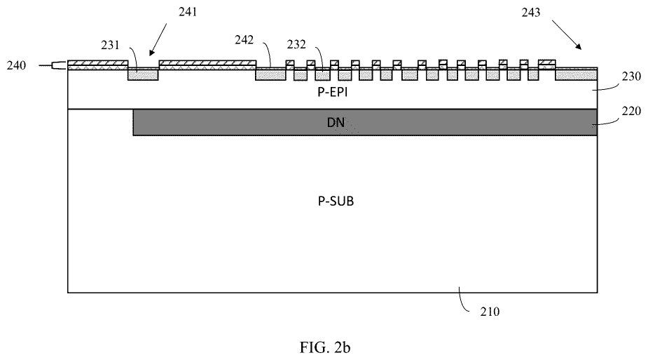

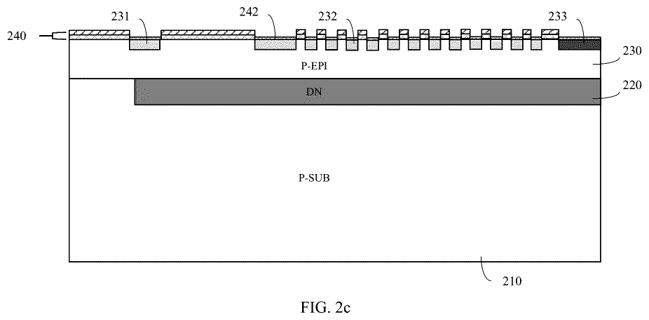

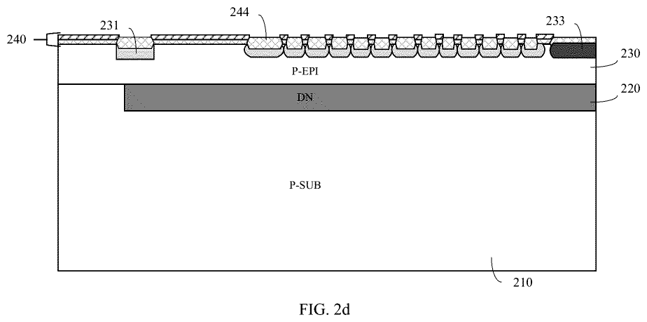

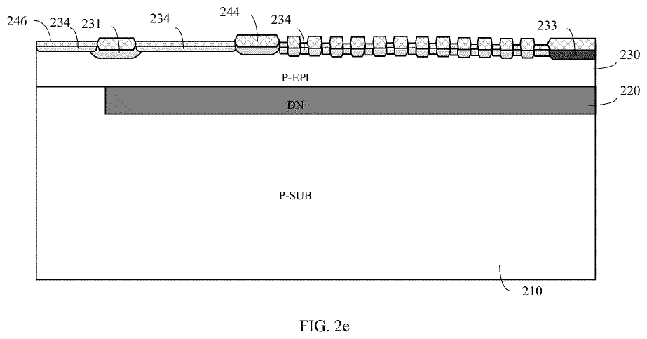

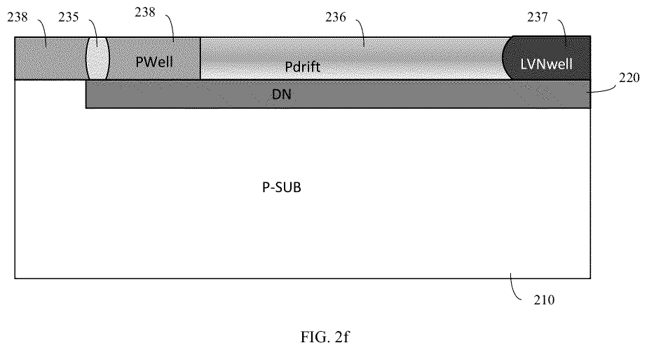

Referring to FIG. 2a, according to an embodiment of the present disclosure, the substrate 210 is a semiconductor substrate, which is made of undoped monocrystalline silicon, monocrystalline silicon doped with impurities, silicon on insulator (SOI), stacked silicon-on-insulator (SSOI), stacked silicon germanium on insulator (S—SiGeOI), silicon germanium on insulator (SiGeOI), germanium on insulator (GeOI), or the like. In the embodiment shown in FIG. 2a, the substrate 210 is made of monocrystalline silicon, that is, the substrate 210 is a P-type silicon substrate. The N-type buried layer 220 is provided in the substrate 210. The P-type region 230 is formed on the N-type buried layer 220. The P-type region 230 may be formed in an epitaxial manner, or a non-epitaxial manner (a buried DN is first implanted in a complete substrate, and then P is implanted to form a P-doped region). The mask layer 240 is located on the P-type region 230, and includes a silicon oxide layer 246 and a silicon nitride layer 248 on the silicon oxide layer 246. Specifically, the silicon oxide layer 246 may be made of silicon dioxide, and the silicon nitride layer 248 may be made of silicon nitride.

In one embodiment, the N-type buried layer 220 may be firstly formed in the substrate 210, the P-type region 230 may then be formed on the N-type buried layer 220, and the silicon oxide layer 246 and the silicon nitride layer 248 may be deposited on the P-type region 230 to form the mask layer 240.

Step S120, the mask layer is patterned to form at least two implantation windows.

In one embodiment, a photoresist is coated on the mask layer 240, and then the photoresist is exposed using an N-well photoresist mask, a photoresist layer 292 as shown in FIG. 2a is obtained after development. Next, the mask layer 240 is etched using the photoresist layer 292 as an etch barrier layer to remove excess portions of the mask layer 240, so as to form the plurality of implantation windows as shown in FIG. 2a. The plurality of implantation windows include a high-voltage N-well implantation window 241 and a low-voltage N-well implantation window 243, and may further include a plurality of N-type ion implantation windows 245 located between the high-voltage N-well implantation window 241 and the low-voltage N-well implantation window 243. Referring to FIG. 2a, in one embodiment, among the plurality of N-type ion implantation windows 245, a spacing d between adjacent windows is 1.0 to 2.0 microns, and a width w of each N-type ion implantation window is 2.0 to 4.0 microns.

In one embodiment, a thin oxide layer 242 is further formed on a surface of the P-type region 230 at each implantation window.

Step S130, an N-type ion implantation is performed through the plurality of implantation windows, and a high-voltage N-well doped region and a low-voltage N-well doped region are formed in the P-type region.

In one embodiment, the N-type ion implantation in step S130 includes two implantation steps. Referring to FIG. 2b, a first N-type ion implantation forms the high-voltage N-well doped region 231 in the P-type region 230 below each implantation window. Then, the photoresist layer 292 is removed, and a photoresist is coated again, which is then exposed using a low-voltage N-well photoresist mask. The photoresist layer after exposure covers the high-voltage N-well implantation window 241 and each N-type ion implantation window, but exposes the low-voltage N-well implantation window 243. Referring to FIG. 2c, the second N-type ions are implanted into the P-type region 230 below through the low-voltage N-well implantation window 243, and superpose with the N-type ions implanted in the first step to form the low-voltage N-well doped region 233. In one embodiment, an implantation dosage of the second N-type ion implantation is greater than an implantation dosage of the first N-type ion implantation, such that a doping concentration of the low-voltage N-well doped region 233 is higher than a doping concentration of the high-voltage N-well doped region 231.

Referring to FIG. 2b, in this embodiment, an N-type drift region doping adjustment region 232 is formed below each N-type ion implantation window 245 by the first implantation. The N-type doped drift region doping adjustment region 232 can adjust a doping concentration of a drift region formed in subsequent steps.

In one embodiment, the ion source for the two N-type ion implantations in step S130 is phosphorus.

Step S140, an oxide layer is formed on a surface of the P-type region at each implantation window.

Referring to FIG. 2d, in one embodiment, the oxide layer 244 is formed by thickening the thin oxide layer 242 on the surface of the P-type region 230 at each implantation window through a high-temperature oxidation. The high-temperature oxidation is a thermal annealing with oxygen introducing, or other high-temperature treatment with oxygen introducing. The N-type ions implanted in step S130 diffuse during annealing.

Step S150, at least a part of the mask layer is removed.

Since subsequent P-type ions are implanted from a position of the mask layer 240, a part of the mask layer 240 is removed in this step. In one embodiment, step S150 is to remove the silicon nitride layer 248 in the mask layer 240, and the silicon oxide layer 246 will be preserved.

Step S160, a P-type ion implantation is performed on the P-type region to form a P-type doped region.

Referring to FIG. 2e, when the P-type ion implantation is performed on the P-type region 230, the oxide layer 244 blocks the implantation of P-type ions. P-type ions are implanted from a position covered by the silicon oxide layer 246 in the previous step to form the P-type doped region 234. If P-type ions diffuses into a region of the P-type region 230 where N-type ions are implanted, they will be neutralized by N-type ions.

In one embodiment, the ion source for the P-type ion implantation in step S160 is boron.

Step S170, a thermal annealing is performed.

Referring to FIG. 2f, the thermal annealing is performed again to promote diffusion of the high-voltage N-well doped region 231, the low-voltage N-well doped region 233, and the P-type doped region 234, such that bottoms thereof reach the N-type buried layer 220. A high-voltage N-type well region 235 is formed after the high-voltage N-well doped region 231 is thermally annealed, and a low-voltage N-type well region 237 is formed after the low-voltage N-well doped region 233 is thermally annealed. Both the high-voltage N-type well region 235 and the low-voltage N-type well region 233 are in contact with the N-type buried layer 220. A drift region 236 and two P-type well regions 238 are formed after the P-type doped region 234 is thermally annealed. The two P-type well regions 238 are formed on two sides of the high-voltage N-type well region 235, respectively. The drift region 236 is formed between the P-type well region 238 adjacent to the low-voltage N-type well region 237 and the low-voltage N-type well region 237. Since the N-type drift region doping adjustment region 232 is formed in advance in a region that the drift region 236 is located, during the process of forming the drift region 236 after the P-type doped region 234 is thermally annealed in step S170, the N-type drift region doping adjustment region 232 neutralizes a part of P-type ions in the drift region 236, such that a doping concentration of the drift region 236 is less than a doping concentration of the P-type well region 238. In addition, a dosage of the P-type ion implantation in step S160 may be greater than the dosage of the first N-type ion implantation in step S130, so as to effectively ensure that the P-type drift region 236 is formed after the P-type doped region 234 is thermally annealed in step S170.

In one embodiment, a doping concentration of the high-voltage N-type well region 235 is less than a doping concentration of the low-voltage N-type well region 237. The doping concentrations of the high-voltage N-type well region 235 and the low-voltage N-type well region 237 range from 1e11 cm⁻² to 1e13 cm⁻².

In one embodiment, the doping concentrations of the drift region 236 and the P-type well region 238 range from 1e11 cm⁻² to 1e13 cm⁻².

Step S180, a source doped region, a drain doped region, and a gate are formed.

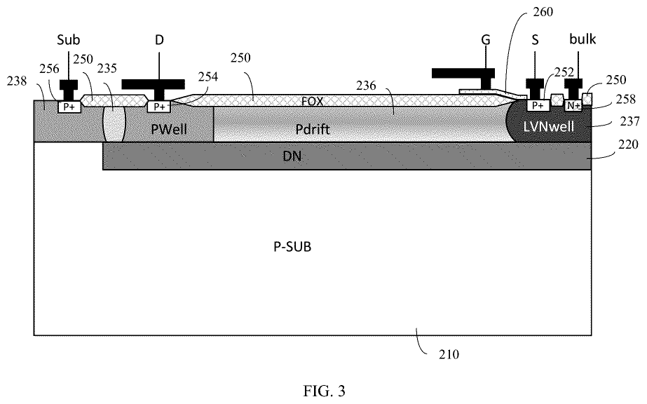

Referring to FIG. 3, in one embodiment, the source doped region 252 is formed in the low-voltage N-type well region 237 by photolithography and ion implantation processes. The drain doped region 254 is formed in the P-type well region 238 between the high-voltage N-type well region 235 and the drift region 236 by photolithography and ion implantation processes. The source doped region 252 and the drain doped region 254 have P-type doping. Specifically, the source doped region 252 and the drain doped region 254 are P+ regions. The gate 260 is formed between the source doped region 252 and the drain doped region 254 by deposition, photolithography, and etching processes.

In one embodiment, prior to forming the gate 260, the method further includes a step of forming a field effect oxide layer 250 on the drift region 236. The gate 260 formed of polycrystalline silicon extends from an edge of the source doped region 252 in a direction toward the drain doped region 254 to be above the field effect oxide layer 250.

In one embodiment, after step S180, the method further includes a step of forming a source metal electrode S, a drain metal electrode D, and a gate metal electrode G. The source metal electrode S is located on the source doped region 252 and is electrically connected to the source doped region 252. The drain metal electrode D is located on the drain doped region 254 and is electrically connected to the drain doped region 254. The gate metal electrode G is located on the gate electrode 260 and is electrically connected to the gate electrode 260. A part of the drain metal electrode D located above the field effect oxide layer 250 serves as a drain metal field plate, and a part of the gate metal electrode G located above the field effect oxide layer 250 serves as a gate metal field plate.

In one embodiment, the method further includes a step of forming a substrate leading-out region 256 and a body region 258. The substrate leading-out region 256 is formed in the P-type well region 238 on a side of the high-voltage N-type well region 235 away from the drift region 236, and the substrate leading-out region 256 has P-type doping. The body region 258 is formed in the low-pressure N-type well region 237, and the body region 258 has N-type doping. The source doped region 252 is located between the body region 258 and the drift region 236. In one embodiment of the present disclosure, the substrate leading-out region 256 is a P+ region, and the body region 258 is an N+ region.

In one embodiment, the aforementioned step of forming the field effect oxide layer 250 simultaneously forms the field effect oxide layer 250 on a surface of the drift region 236 between the substrate leading-out region 256 and the drain doped region 254, so as to form the field effect oxide layer 250 on a surface of the drift region 236 on both sides of the body region 258.

According to the aforementioned method for manufacturing the P-type laterally diffused metal oxide semiconductor device, the patterned mask layer forms segmented implantation windows 245. After N-type ions are implanted, by covering the oxide layer 244 on surfaces of implantation windows, the oxide layer 244 can serve as a barrier layer when P-type ions are subsequently implanted. Therefore, it is not necessary to prepare a separately photolithography mask for the P-type ion implantation, thereby effectively simplifying a manufacturing process of PLDMOS device, which can be compatible with a manufacturing process of NLDMOS.

According to one embodiment, a P-type laterally diffused metal oxide semiconductor device (PLDMOS) is further provided, which can be applied to a high-voltage integrated circuit with a breakdown voltage of 600V. The PLDMOS may be manufactured by the method for manufacturing the P-type laterally diffused metal oxide semiconductor device according to any of the aforementioned embodiment. Referring to FIG. 3, the PLDMOS includes a P-type substrate 210, an N-type buried layer 220 provided in the substrate 210, and a P-type region is provided on the N-type buried layer 210 and the substrate 210. A high-voltage N-type well region 235, a low-voltage N-type well region 237, a P-type doped drift region 236, and a P-type well region 238 are provided in the P-type region. A field effect oxide layer 250 is provided on the P-type region. A gate 260 is provided on the field effect oxide layer 250, which may be specifically a polycrystalline silicon gate, and the gate 260 is located above the low-voltage N-type well region 237 and the field effect oxide layer 250. A cathode N-type heavily doped region (serving as a body region 258) and a cathode P-type heavily doped region (serving as a source doped region 252) are provided in the low-voltage N-type well region 237, and the body region 258 is connected to a body region metal electrode bulk. The source doped region 252 is located between the gate 260 and the body region 258 and is connected to a source metal electrode S. An anode P-type heavily doped region (serving as a substrate leading-out region 256) is provided in the P-type well region 238, and the substrate leading-out region 256 is connected to a substrate leading-out region metal electrode Sub. An anode P-type heavily doped region (serving as a drain doped region 254) is provided in the P-type well region 238, and the drain doped region 254 is located between the high-voltage N-type well region 235 and the drift region 236 and is connected to a drain metal electrode D.

Referring to FIG. 3, a first side of a front side metal layer (i.e., the drain metal electrode D) of a drain is located above the field effect oxide layer 250 between the drain doped region 254 and the substrate leading-out region 256. A second side is located above the field effect oxide layer 250 on the drift region 236, and the second side extends in a direction towards the drift region 236 to form a drain metal field plate. A first side of a front side metal layer (i.e., the gate metal electrode G) of the gate is located above the field effect oxide layer 250 on the drift region 236. The second side is located above the gate 260, and the first side extends above the drift region 236 to form a gate metal field plate.

It should be understood that although the steps in the flow chart of the present disclosure are sequentially displayed as indicated by the arrows, these steps are not necessarily performed in the order indicated by the arrows. Unless explicitly stated herein, the performing order of these steps is not be limited strictly, and these steps may be performed in other orders. Moreover, at least a part of the steps in the flow chart of the present disclosure may include a plurality of steps or phases, which are not necessary to be performed simultaneously, but may be performed at different times, and for the performing order thereof, it is not necessary to be performed sequentially, but may be performed by turns or alternately with other steps or steps of other steps or at least a part of the phases.

Each of the technical features of the above-mentioned embodiments may be combined arbitrarily. To simplify the description, not all the possible combinations of each of the technical features in the above embodiments are described. However, all of the combinations of these technical features should be considered as within the scope of this disclosure, as long as such combinations do not contradict with each other.

The above embodiments merely illustrate several embodiments of the present disclosure, and the description thereof is specific and detailed, but it shall not be constructed as limiting the scope of the present disclosure. It should be noted that a plurality of variations and modifications may be made by those skilled in the art without departing from the conception of the present disclosure, which are all within the scope of protection of the present disclosure. Therefore, the protection scope of the patent of the present disclosure shall be subject to the appended claims.

1. A method for manufacturing a P-type laterally diffused metal oxide semiconductor device, comprising:
forming an N-type buried layer in a substrate, forming a P-type region on the N-type buried layer, and forming a mask layer on the P-type region;
patterning the mask layer to form at least two implantation windows;
performing an N-type ion implantation through the at least two implantation windows to form a high-voltage N-well doped region and a low-voltage N-well doped region in the P-type region, wherein a doping concentration of the low-voltage N-well doped region is higher than a doping concentration of the high-voltage N-well doped region;
forming an oxide layer on a surface of the P-type region at each implantation window;
removing at least a part of the mask layer;
performing a P-type ion implantation on the P-type region to form a P-type doped region;
diffusing the P-type doped region by a thermal annealing to form a drift region and two P-type well regions, diffusing the high-voltage N-well doped region to form a high-voltage N-type well region, and diffusing the low-voltage N-well doped region to form a low-voltage N-type well region; wherein the drift region is located between the high-voltage N-type well region and the low-voltage N-type well region, the two P-type well regions are located on two sides of the high-voltage N-type well region, respectively, and one of the two P-type well region is located between the high-voltage N-type well region and the drift region; and
forming a source doped region, a drain doped region, and a gate; wherein the source doped region is located in the low-voltage N-type well region, the drain doped region is located in one P-type well region and is located between the high-voltage N-type well region and the drift region, the gate is located between the source doped region and the drain doped region, and the source doped region and the drain doped region have P-type doping.

2. The method according to claim 1, wherein the at least two implantation windows comprise a high-voltage N-well implantation window and a low-voltage N-well implantation window;
performing the N-type ion implantation through each implantation window and forming the high-voltage N-well doped region and the low-voltage N-well doped region in the P-type region comprises:
performing a first N-type ion implantation through the high-voltage N-well implantation window and the low-voltage N-well implantation window to form the high-voltage N-well doped region;
forming a photoresist layer on the P-type region, the photoresist layer covering the high-voltage N-well implantation window and exposing the low-voltage N-well implantation window; and
performing a second N-type ion implantation through the low-voltage N-well implantation window to form the low-voltage N-well doped region in the P-type region.

3. The method according to claim 2, wherein the at least two implantation windows further comprise a plurality of N-type ion implantation windows located between the high-voltage N-well implantation window and the low-voltage N-well implantation window;
wherein performing the first N-type ion implantation comprises: forming a corresponding number of N-type drift region doping adjustment regions in the P-type region through the plurality of N-type ion implantation windows; and
covering the plurality of N-type ion implantation windows by the photoresist layer.

4. The method according to claim 3, wherein adjacent windows in the plurality of N-type ion implantation windows are spaced apart by 1.0 to 2.0 microns.

5. The method according to claim 3, wherein a width of each N-type ion implantation window is 2.0 to 4.0 microns.

6. The method according to claim 3, wherein a dosage of the P-type ion implantation is greater than a dosage of the first N-type ion implantation.

7. The method according to claim 1, wherein the mask layer comprises a silicon dioxide layer and a silicon nitride layer located on the silicon dioxide layer, and the step of removing at least a part of the mask layer is to remove the silicon nitride layer.

8. The method according to claim 1, wherein prior to forming the gate, the method further comprises:
forming a field effect oxide layer on the drift region, wherein the field effect oxide layer is located between the source doped region and the drain doped region;
wherein the gate is a polycrystalline silicon gate extending onto the field effect oxide layer.

9. The method according to claim 8, further comprising:
forming a source metal electrode, a drain metal electrode, and a gate metal electrode; wherein the source metal electrode is located on the source doped region and is electrically connected to the source doped region, the drain metal electrode is located on the drain doped region and is electrically connected to the drain doped region, the gate metal electrode is located on the gate and is electrically connected to the gate, a part of the drain metal electrode located above the field effect oxide layer serves as a drain metal field plate, and a part of the gate metal electrode located above the field effect oxide layer serves as a gate metal field plate.

10. The method according to claim 1, further comprising:
forming a substrate leading-out region, wherein the substrate leading-out region is formed in a P-type well region on a side of the high-voltage N-type well region away from the drift region, and the substrate leading-out region has P-type doping; and
forming a body region in the low-voltage N-type well region, wherein the body region has N-type doping, and the source doped region is located between the body region and the drift region.

11. The method according to claim 1, wherein an N-type ion source for the N-type ion implantation is phosphorus, and a doping concentration thereof is 1e11 cm⁻² to 1e13 cm⁻²; and a P-type ion source for the P-type ion implantation is boron, and a doping concentration thereof is 1e11 cm⁻² to 1e13 cm⁻².

12. The method according to claim 1, wherein a doping concentration of the drift region is less than a doping concentration of the P-type well region.

13. The method according to claim 1, wherein both the high-voltage N-type well region and the low-voltage N-type well region are in contact with the N-type buried layer.

14. A P-type laterally diffused metal oxide semiconductor device, comprising:
a substrate;
an N-type buried layer provided in the substrate;
a P-type region provided on the N-type buried layer and the substrate;
a high-voltage N-type well region, a low-voltage N-type well region, a drift region, and two P-type well regions that are provided in the P-type region;
a field effect oxide layer provided on the P-type region;
a gate located on the low-voltage N-type well region and the field effect oxide layer;
a body region and a source doped region that are provided in the low-voltage N-type well region, wherein the body region is connected to a body region metal electrode, and the source doped region is located between the gate and the body region and is connected to a source metal electrode;
a substrate leading-out region provided in one of the two P-type well regions and connected to a substrate leading-out region metal electrode; and
a drain doped region provided in another of the two P-type well regions, wherein the drain doped region is located between the high-voltage N-type well region and the drift region and is connected to a drain metal electrode.

15. The P-type laterally diffused metal oxide semiconductor device according to claim 14, wherein a doping concentration of the drift region is less than a doping concentration of the P-type well region.

16. The P-type laterally diffused metal oxide semiconductor device according to claim 14, wherein a first side of the drain metal electrode is located above the field effect oxide layer between the drain doped region and the substrate leading-out region, a second side of the drain metal electrode is located above the field effect oxide layer on the drift region, and the second side extends in a direction towards the drift region to form a drain metal field plate.

17. The P-type laterally diffused metal oxide semiconductor device according to claim 14, further comprising a gate metal electrode located on the gate and is electrically connected to the gate, wherein a first side of the gate metal electrode is located above the field effect oxide layer on the drift region, a second side of the gate metal electrode is located above the gate, and the first side extends above the drift region to form a gate metal field plate.

18. The P-type laterally diffused metal oxide semiconductor device according to claim 14, wherein the P-type laterally diffused metal oxide semiconductor device is applied to a high-voltage integrated circuit with a breakdown voltage of 600V.

19. The P-type laterally diffused metal oxide semiconductor device according to claim 14, wherein the substrate is a P-type substrate.

20. The P-type laterally diffused metal oxide semiconductor device according to claim 14, wherein the body region is a cathode N-type heavily doped region, and the source doped region is a cathode P-type heavily doped region.
